(19) United States
(12) Patent Application Publication
(10) Pub. No.: US 2011/0232731 A1
(43) Pub. Date: Sep. 29, 2011

(54) HIGH EFFICIENCY HYBRID ORGANIC-INORGANIC PHOTOVOLTAIC CELLS

(76) Inventors: Gon NAMKOONG, Yorktown, VA (US); Helmut BAUMGART, Yorktown, VA (US); Keejoo LEE, Norfolk, VA (US)

(21) Appl. No.: 12/898,260

(22) Filed: Oct. 5, 2010

Related U.S. Application Data
(60) Provisional application No. 61/318,695, filed on Mar. 29, 2010.

(51) Int. Cl. H01L 31/02; H01L 31/06; H01L 31/0224

(52) U.S. Cl. 136/255; 438/98; 257/E31.126

(57) ABSTRACT

Devices including photovoltaic cells and methods of manufacture are disclosed. A photovoltaic cell includes a first electrode layer, at least one photoactive layer disposed on first electrode layer, a second electrode layer disposed on the photoactive layer, at least one first carrier collector structure with a first work function electrically coupled to the first electrode layer and extending partially in to the photoactive layer, and at least one second carrier collector structure with a second work function electrically coupled to the second electrode layer and extending partially into the photoactive layer. In the cell, the first carrier collector structure extends towards the second electrode layer without physically contacting the second carrier collector structure, and the second carrier collector structure extends towards the first electrode layer without physically contacting the first carrier collector structure. Further, at least one of the first and second electrode layers is optically transparent.

### CROSS-REFERENCE TO RELATED APPLICATIONS

This application claims the benefit of Provisional Application Ser. No. 61/318,695 entitled “HIGH EFFICIENCY HYBRID ORGANIC-INORGANIC SOLAR CELLS”, filed Mar. 29, 2010, which is herein incorporated by reference in its entirety.

### FIELD OF THE INVENTION

The present invention relates to photovoltaic cells, and more specifically methods for fabricating high efficiency hybrid organic-inorganic photovoltaic cells and devices therefrom.

### BACKGROUND

The need for easily produced, flexible, and reliable energy sources has spurred world-wide research efforts aimed at addressing the development of organic photovoltaic cells. Three major challenges in organic photovoltaic cells include enhancement of energy conversion efficiencies, stability in various environments, and process-scalability to large areas. Among three challenges, the power conversion efficiency is of highest important in order to complete with other technologies. Current energy conversion efficiency of organic photovoltaic cells is around 7% which is far below that of other photovoltaic cells technologies. To overcome such a low efficiencies, planar bulk heterojunction photovoltaic cells, nanostructured hybrid organic-inorganic photovoltaic cells, and tandem photovoltaic cells have been proposed.

In planar bulk heterojunction devices, the organic polymers and fullerene derivatives are randomly mixed to form nanoscale donor/acceptor interfaces. In this type of structure, efficient dissociation of photo-generated excitons occurs at large polymer-fullerene interfaces and yields dissociation efficiencies approaching 100%. Subsequently, these charge carriers move toward their respective electrodes, where free carriers are transported by hopping via percolated fullerene molecules and the polymer network. A drawback of such devices is inferior charge transfer properties that result from disordered percolating pathways. Therefore, one of the main challenges is to efficiently collect dissociated free carriers at the interfaces. Another challenge encountered with such photovoltaic cells is that the absorption and charge collection efficiencies cannot be optimized simultaneously. Further, photocurrent in these photovoltaic cells drops drastically after reaching a peak at a photoactive layer thickness of ˜70 nm.

Hybrid nanostructured organic-inorganic photovoltaic cells are based on the concept of inorganic nanoelectrodes being closely arrayed within the exciton diffusion length so that charge collection is maximized through rapid transport. A current technical challenge associated with such devices is how to assemble nanoelectrodes over a large 2D area so that they are spaced close enough to each other to be within the effective exciton diffusion length (5-20 nm). In addition, there are other challenges including infiltration of polymer, polymer wetting, control of nanoscale morphologies and phase separation, and interface modification. Therefore, while the concept of nanostructured organic-inorganic photovoltaic cells is both elegant and promising in principle, the realization of such devices is technologically challenging. Further, unbalanced charge transport is inevitable in these cells since only one type of carrier can be rapidly collected through the transparent nanoelectrode. The other type of carrier must travel in a slow hopping transport process through disordered organic blends to the top electrode. Such unbalanced charge transport is exacerbated with increased device thickness and causes space charge effects. As a result, the recombination rate and series resistance both increase and limit the power conversion efficiency.

Tandem photovoltaic cells provide the advantage that it expands the overall absorption bandwidth by stacking active organic blends of different bandgaps in series or parallel. However, while series-tandem photovoltaic cells are configured to increase VOC (open circuit voltage), they are limited by a current matching condition where the current must be matched through each individual cell. In other words, each cell requires the same number of photons to be absorbed for optimal performance. As an alternative, a parallel configuration is proposed that increases ISC (short circuit current) and replaces the current matching condition with a voltage matching requirement. In this way, overall performance is limited by the cell with the smallest VOC. However, these parallel tandem devices still suffer from low VOC (typical less than 1.0 V) that must be increased further.

### SUMMARY

Embodiments of the invention concern methods for fabricating photovoltaic devices and device therefrom. In a first embodiment of the invention, a device is provided. The device includes at least one photovoltaic cell includes at least one first electrode layer, at least one photoactive layer disposed on first electrode layer, and at least one second electrode layer disposed on the photoactive layer. The device also includes at least one first carrier collector structure with a first work function electrically coupled to the first electrode layer and extending partially in to the photoactive layer, and at least one second carrier collector structure with a second work function different from the first work function electrically coupled to the second electrode layer and extending partially into the photoactive layer. In the device, the first carrier collector structure extends towards the second electrode layer without physically contacting the second carrier collector structure and the second carrier collector structure extends towards the first electrode layer without physically contacting the first carrier collector structure. Further, at least one of the first and second electrode layers is transparent.

In a second embodiment of the invention, a method for fabricating a photovoltaic device is provided. The method includes the steps of providing a first electrode layer that is optically transparent and electrically conductive and defining in an upper surface of the first electrode layer a plurality of first carrier collection structures. The method also includes the step of forming one or more conformal layers over the upper surface of the first electrode layer defining one or more gap regions between adjacent ones of the plurality of first carrier collection structures, where the conformal layers includes at least a first electrically insulating layer. The method further includes the steps of depositing at least one electrically conductive layer over the conformal layers, the electrically conductive layer configured to substantially fill the gap regions, and removing at least a portion of the electrically conductive layer to define a plurality of isolated second carrier collection structures between the plurality of first carrier collection structures. The method also includes the step of removing a portion of the conformal layers to expose sidewall portions of the plurality of first carrier collection structures and sidewall portions of the plurality of second carrier collection structures.

### BRIEF DESCRIPTION OF THE DRAWINGS

FIG. 1 shows a schematic drawing of a photovoltaic cells device architecture in accordance with an embodiment of the invention;

FIG. 2 is an X-Y plot of current density and efficiency as a function of photoactive layer thickness for photovoltaic cells devices using conventional planar architectures;

FIG. 3 is an X-Y plot of simulated efficiency versus photoactive layer thickness for a photovoltaic cells device configured according to architecture of FIG. 1 for varying lateral spacing of the anode and cathode and for a lateral thickness of the anode and the cathode of 25 nm;

FIG. 4 is an X-Y plot of efficiency as a function of cathode/anode lateral thickness (t) for different lateral spacing (d) of the anode and cathode for the architecture of FIG. 1;

FIG. 5 is a schematic drawing of another photovoltaic cells device architecture in accordance with an embodiment of the invention;

FIGS. 6A-6C are top-down views of exemplary anode and cathode arrangements corresponding to the architecture in FIG. 1;

FIGS. 7A-7E show various views during a first exemplary process for fabricating an interdigitated array of photovoltaic cells in accordance with an embodiment of the invention and corresponding to architecture of FIG. 1;

FIGS. 8A-8E show various views during an alternate exemplary process for forming the structure in FIG. 7B;

FIGS. 9A-9D show various views during exemplary processes for completing fabrication of an interdigitated array of photovoltaic cells in accordance with an embodiment of the invention and corresponding to architecture of FIG. 1;

FIGS. 10A-10C show various views during an exemplary process for fabricating an interdigitated array of photovoltaic cells in accordance with an embodiment of the invention and corresponding to architecture of FIG. 5;

FIGS. 11A and 11B show cross-sectional SEM images of Al₂O₃ at the bottom of 5 μm deep trench for an ALD process and pulsed PECVD process, respectively;

FIGS. 12A-12C schematically illustrate a method of fabricating photovoltaic cells using a tube-in-tube method based on a template;

FIG. 13A is a top-down SEM image of mono dispersed polystyrene nanosphere on an ITO/glass surface;

FIG. 13B is a top-down SEM image of the ITO/glass surface showing the nanoscale metal mask patterns obtained after nanosphere removal;

FIG. 14A is a schematic diagram of a side view of an ITO/glass substrate after PS nanosphere lithography;

FIG. 14B is a top-down view of the ITO/glass substrate of FIG. 12A;

FIG. 15A shows a top-down scanning electron microscope (SEM) image of the pore structure of a 140 μm thick, planarized AAO substrate;

FIG. 15B shows a scanning electron microscope (SEM) image of the pore structure of a cleaved 140 μm thick, planarized. AAO substrate;

FIGS. 16A and 16A are SEM images of the front side and back side, respectively, of a silicon substrate-based porous membrane;

FIGS. 17A-17C show various SEM images of the results of tube formation processes based on an AAO template.

FIG. 18 shows various SEM images of the tube-in-tube formation process using a template formed from a silicon substrate;

FIGS. 19A and 19B present the thermodynamic modeling diagrams for Al₂O₃ and ZnO and show the distributions of the fraction of all species at different pH values calculated at 298 K for a 0.001 mM solution;

FIG. 20 shows ZnO nanotubes that were preferentially etched along the grain boundaries even though the proper pH value for selectively etching Al₂O₃ was used;

FIG. 21 is a SEM image of cleaved ZnO nanotubes released from an AAO template; and

FIG. 22 is a schematic of the energy level of polymer-fullerene/electrode (left) and band alignment at the anode interface after contact (right).

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

As described above, the efficiency of organic photovoltaic cells devices lag behind the efficiency of other photovoltaic cells technologies. In view of the limitations of such devices, the various embodiments of the invention provide a new organic photovoltaic cells architecture with higher cell efficiency as compared to conventional organic photovoltaic cells architectures.

Photovoltaic Cells Architecture

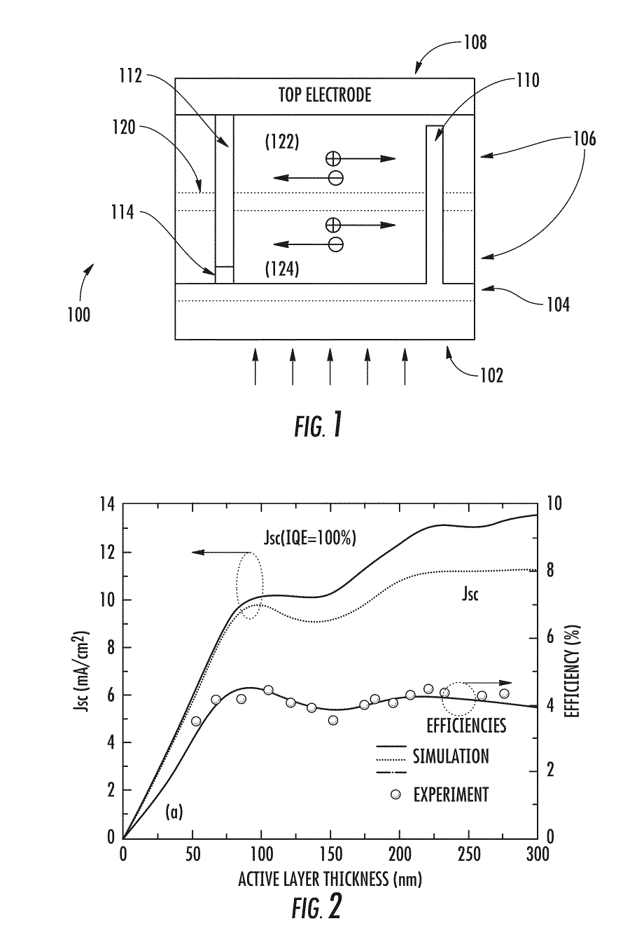

Referring now to FIG. 1, there is shown a schematic drawing of a photovoltaic cells device architecture 100 in accordance with an embodiment of the invention. As shown in FIG. 1, the architecture 100 includes a transparent supporting substrate 102, a transparent bottom electrode layer 104 disposed on substrate 102, a photoactive layer 106 disposed on bottom electrode 104, and a top electrode layer 108 disposed on photoactive layer.

In the various embodiments of the invention, the bottom electrode 104 can be formed using any type of transparent conducting film (TCF), including transparent conducting oxides (TCO) or transparent conducting polymers (TCP). Exemplary materials will be described below in greater detail with to the various fabrication processes. Further, as shown in FIG. 1, the bottom electrode 104 can be formed on a supporting substrate 102, such as a layer of glass or indium tin oxide (ITO). However, the various embodiments of the invention are not limited in this regard. Rather, the bottom electrode 104 and the substrate can be integrally formed to allow the bottom electrode 104 to be directly contacted via substrate 102.

In addition to structures 102-108, the architecture 100 includes a first carrier collection or anode structure 110 and a second carrier collection or cathode structure 112 extending vertically into photoactive layer 106 from the bottom electrode 104 and top electrode 108, respectively. Although carrier collection structures will be described throughout as being associated with one of a cathode and an anode, this is for illustrative purposes only. One of ordinary skill in the art will recognize that the carrier collection structures providing cathode and anodes can be interchangeable in the various architectures and devices described herein.

In the various embodiments, the materials comprising the anode 110 and the cathode 112 are selected to provide a difference in their respective work function. The anode 110 and the cathode 112 can be substantially parallel to each other. Further, the anode 110 and the cathode 112 can extend in directions that are substantially normal to the bottom electrode 104 and the top electrode 108, respectively. As used herein with respect to comparison of directions, the term “substantially” refers to being within 20 degrees of the stated direction. In the various embodiments, the anode 110 and the cathode 112 are configured to extend partially through photoactive layer 106 to prevent contact to and shorting of top electrode 108 and bottom electrode 104 to the anode 110 and cathode 112, respectively. In some configurations, electrical insulator portions 114 can be provided to further electrically isolate the anode 110 and the cathode 112 from top electrode 108 and bottom electrode 104, respectively. For example, as shown in FIG. 1, portion 114 is disposed between to ensure that the cathode 112 is not shorted to bottom electrode 104.

The architecture in FIG. 1 operates as follows. First, the photons incident to substrate 102 pass through substrate 102 and bottom electrode 104 into photoactive layer 106. In photoactive layer 106, these photons create photogenerated excitons which efficiently dissociate into free charge carriers. The free carriers are subsequently driven toward their respective electrodes by the lateral electric field formed by the difference in the work function between the materials in the anode 110 and the cathode 112.

In this structure, the photon absorption and charge collection directional pathways are decoupled. In particular, they are substantially perpendicular to each other. Accordingly, light absorption and charge collection can be separately controlled. For example, the photocurrents can be improved with by adjusting the thickness of the photoactive layer 106 while the spacing between the anode 110 and cathode 112 can be laterally controlled to independently adjust charge (i.e., free) carrier collection efficiency.

The performance of the architecture 100 was estimated using in-house simulation package using organic drift-diffusion models combined with Onsager-Braun model. In particular, the benefits of using architecture are more evident when its performance is compared with that of the planar cells, as shown in FIG. 2.

FIG. 2 is an X-Y plot of current density (JSC) and efficiency as a function of photoactive layer thickness for photovoltaic cells devices using conventional planar architectures. As shown in FIG. 2, the energy conversion efficiencies of planar structures using widely used P3HT:PCBM organic photoactive layers is around 4%, even with increasing photoactive layer thickness up to 300 nm. This is due to the fact that the recombination process becomes more pronounced with increased thickness, and as a result, current density tends to saturate or drop with increased thickness, as shown FIG. 2A.

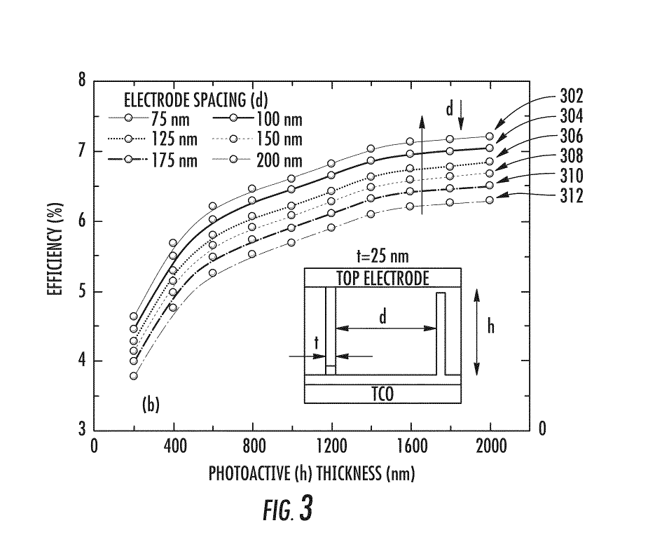

In contrast, when same device parameters are applied to architecture 100, its efficiency can reach about 7%, as shown in FIG. 3. FIG. 3 is an X-Y plot of simulated efficiency versus photoactive layer thickness for a photovoltaic cells device configured according to architecture 100 for varying lateral spacing of anode 110 and cathode 112 and for a lateral thickness of anode 110 and cathode 112 of 25 nm. In particular, FIG. 3 shows efficiency data for lateral spacing of 75 nm (curve 302), 100 nm (curve 304), 125 nm (curve 306), 150 nm (curve 308), 175 nm (curve 310), and 200 nm (curve 312). As shown in FIG. 3, as the thickness of the photoactive layer is increased from ˜300 nm to 2000 nm, the efficiency is also increased by approximately 2%. Such an improvement in efficiency is believed to be due to the decoupled control of light absorption and charge collection where light absorption increased with increased photoactive height (h). Further, as lateral spacing (d) is decreased from 200 nm to 75 nm, the efficiency can be increased by approximately 1%, as shown by the difference between curves 302 and 312. This improvement is believed ti be due to improved charge collection with smaller lateral spacing (d) of electrodes.

As shown in FIG. 3, device parameters such as active layer thickness (h) and electrode spacing (d) dictate efficiency, and thus JSC. Accordingly, for architecture 100, simulation indicates that an electrode spacing of around 70-90 nm can achieve an internal quantum efficiency of 100% (i.e., where all of charge carriers can be extracted to electrodes).

In addition to active layer thickness (h) and electrode spacing (d), the lateral thickness of anode 110 and cathode 112 can also dictate efficiency. This is illustrated in FIG. 4. FIG. 4 is an X-Y plot of efficiency as a function of cathode/anode lateral thickness (t) for different lateral spacing (d) of anode 110 and cathode 112. In particular, FIG. 4 shows efficiency data for a lateral spacing of 100 nm (curve 402), 150 nm (curve 404), and 200 nm (curve 406). This data was also obtained by simulation with a constant photoactive layer thickness (h) of P3HT:PC71BM of 1000 nm. As shown previously shown in FIG. 3, as the lateral spacing (d) is decreased, efficiency is increased, as shown by the difference between curves 402, 404, and 406. However, as lateral thickness (t) is increased, efficiency is reduced. For example, as shown in curve 502, increasing lateral thickness from 20 nm to 50 nm results in efficiency dropping from ˜6.75% to less than 5.5%. It is worth noting, that as lateral spacing (d) is increased, the rate of reduction in efficiency due to increasing lateral thickness (t) is lessened.

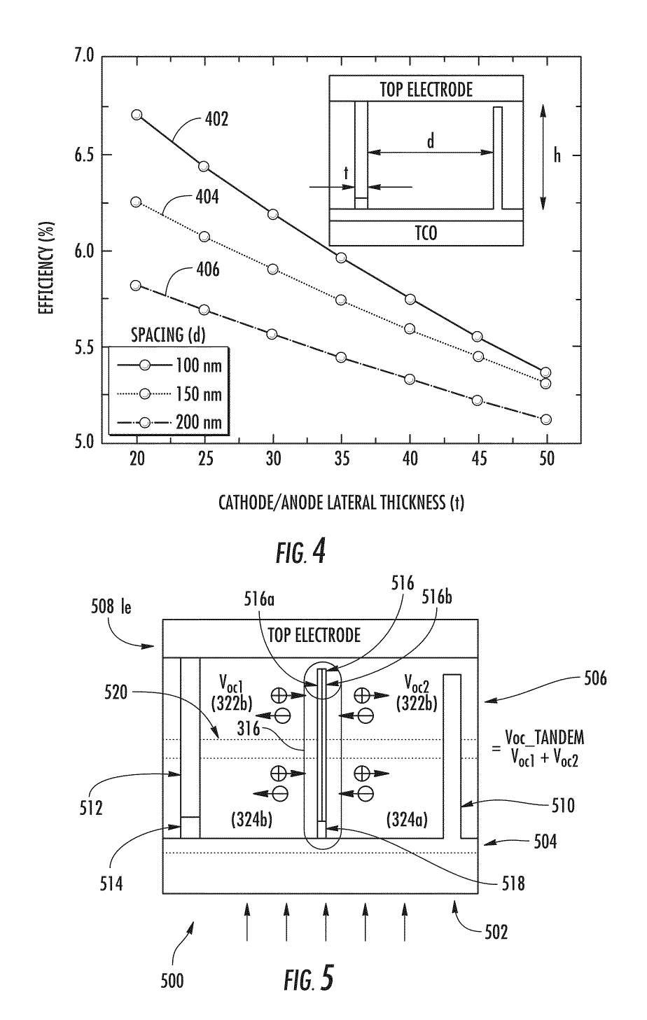

In general, it is difficult to array interdigitated anode-cathode arrays in nanoscale to provide a dense array of photovoltaic cells. Accordingly, in some embodiments of the invention, a recombination center can be provided for architecture 100. This is illustrated in FIG. 5. FIG. 5 is a schematic drawing of another photovoltaic cell device architecture 500 in accordance with an embodiment of the invention. As shown in FIG. 5, the architecture 500 includes a transparent supporting substrate 502, a transparent bottom electrode layer 504 disposed on substrate 502, a photoactive layer 506 disposed on bottom electrode 504, and a top electrode layer 508 disposed on photoactive layer. Additionally, the architecture 500 also includes anode 510, cathode 512, and electrically insulating portions 514. The operation and configuration of components 502-514 in FIG. 5 is substantially similar to that of components 102-114 in FIG. 1. Accordingly, the description of components 102-114 above is sufficient for describing components 502-514 in FIG. 5.

In addition to components 502-514, architecture 500 can also include a recombination center 516 extending vertically through photoactive layer 506 and between anode 510 and cathode 512. In particular, the recombination center 516 can be a combination of an anode layer 516a and a cathode layer 516b arranged to face cathode 512 and anode 510, respectively. The recombination center 516 effectively splits the photoactive layer 506 into two sub-cells, resulting in a series tandem cell. In the various embodiments of the invention, these sub-cells can be designed almost identical in their geometry, potentially producing two identical sets of photovoltaic parameters such as JSC, VOC, and fill factor (FF). Further, architecture 500 can further include additional electrically insulating portions 518 to prevent recombination center 516 from being shorted to either of electrodes 504 and 508.

Although two exemplary architectures are shown in FIGS. 1 and 5, the various embodiments of the invention are not limited in this regard. For example, the architectures in FIGS. 1 and 5 can be further adapted to provide other tandem photovoltaic cells arrangements. For example, architecture 100 can be modified to include at least one dielectric layer 120 within photoactive layer 106 and disposed between the top electrode layer 108 and the bottom electrode layer 104. Thus, the division of the photoactive layer 106 into top and bottom portions thus defines parallel tandem cells. That is, the portion of layer 106 above layer 120 defines a first cell 122 and the portion of layer 106 below layer 120 defines a second cell 124 in parallel with the first cell.

A similar transparent dielectric layer in architecture 500 can be used to define a series/parallel combination of cells. As described above, the recombination center 516 defines the series combination of two serial cells. Thereafter, a transparent dielectric layer 520 can be used to define two parallel cells in each of the serial cells. Resulting in a series/parallel combination of four cells 522a, 522b, 524a, and 524b.

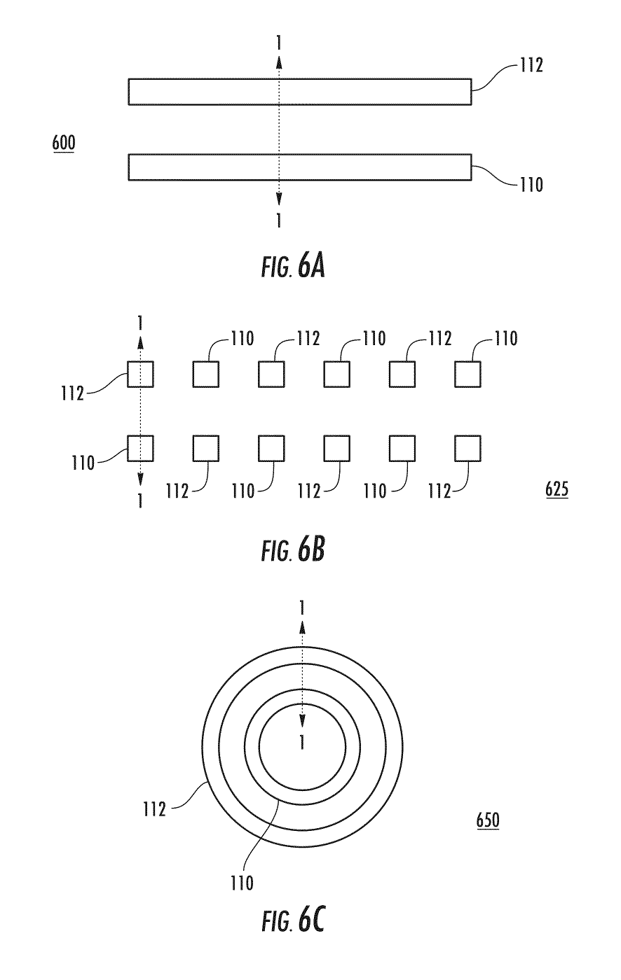

The exemplary architectures 100 and 500 are provided for illustrative purposes and are not intended to represent the complete architecture of a photovoltaic cells in accordance with the various embodiments of the invention. Rather, the exemplary architectures 100 and 500 represent a generalized architecture which can be applied to various photovoltaic cell arrangements, as shown in FIG. 6A-6C.

FIGS. 6A, 6B, and 6C are top-down view of exemplary anode and cathode arrangements 600, 625, and 650, respectively, corresponding to architecture 100 in FIG. 1. Arrangement 600 shows a photovoltaic cells device consisting of alternating rows of anode structures 112 and cathode structures 110, in which the anode structures 110 and cathode structures 112 still correspond to architecture 100, as shown by cutline 1-1 in FIG. 6A. Arrangement 625 shows a photovoltaic cells device consisting of an array of alternating anode structures 112 and cathode structures 110, in which an adjacent pair of one of the anode structures 110 and one of the cathode structures 112 still correspond to architecture 100, as shown by cutline 1-1 in FIG. 6B. Arrangement 650 shows a photovoltaic cells device consisting of a tube-in-tube structure, in which the anode structures 110 and cathode structures 112 still correspond to architecture 100, as shown by cutline 1-1 in FIG. 6C. One of ordinary skill in the art will readily recognize that architecture 500 can be generally applied to such arrangements as well. Further, architectures 100 and 500 can also be extended to other arrangements than those illustrated here.

Interdigitated Array Photovoltaic Cells Fabrication

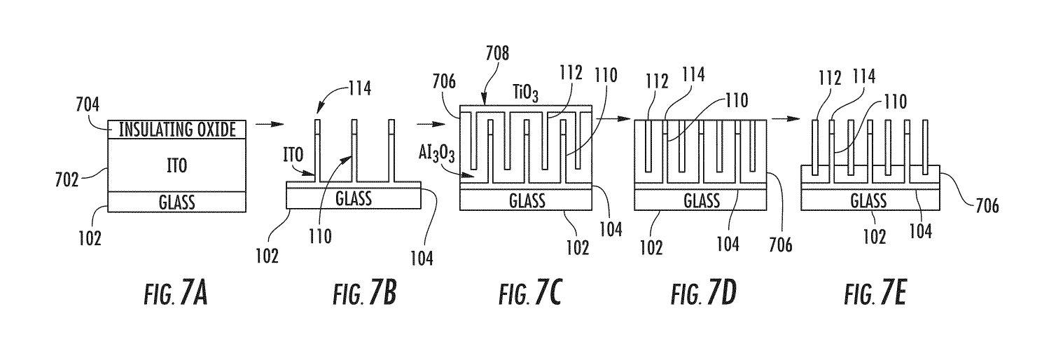

Referring now to FIGS. 7A-7E, there are shown various views during a first exemplary process for fabricating an interdigitated array of photovoltaic cells in accordance with an embodiment of the invention and corresponding to architecture 100. The process begins with formation of a layer of material for forming the bottom electrode 104 and anode 110 on substrate 102, as shown in FIG. 7A. In particular, as shown in FIG. 7A, an ITO layer 702 with a thickness corresponding to the length for the anode 110 is deposited on the substrate 102. However, layer 702 is not limited to ITO and can be a layer of at least one metal oxide such as, for example, molybdenum oxide, vanadium oxide, tungsten oxide, or nickel oxide. Layer 702 can also be a nanostructured metal oxide layer.

Further, at least one electrically insulating oxide layer 704 is deposited on layer 702. Although layer 704 can be any type of insulating oxide, any materials that will become a permanent part of the structure need to be highly transparent and chemically inert over a wide range of pH. For example, layer 704 can be formed from HfO₂, ZrO₂, SiO₂, and SiN. However, the various embodiments are not limited in this regard and other electrically insulating oxides can also be used.

After layers 702 and 704 are formed, layers 702 and 704 can be patterned and etched to define bottom electrode 102, form anodes 112, and, optionally, form isolation features 114, as shown in FIG. 7B. This can be achieved in various ways. For example, in one configuration, a combination of photolithography and etch processes can be used. That is, a photoresist pattern (not shown) can be formed on layer 704. Thereafter, an etch process can be used to transfer this pattern into layers 704 and 702. Such processes can include wet and/or dry etch processes and any intervening cleaning steps. In some processes, the photoresist can be removed after the pattern is first transferred into layer 704 and layer 704 is then used as a hard mask for etching of layer 702. Further, in some processes, any remaining portions of layer 704 can be removed after etching of layer 702.

In some embodiments of the invention, insulating oxide layers, such as layer 704 and other insulating layers, can be deposited using evaporator methods. These insulating oxides must be highly transparent and chemically inert over wide pH ranges since selective chemical etching will be applied later processes. Some candidates include SiO₂, SiN, HfO₂, ZrO₂, which can be deposited using e-beam evaporator.

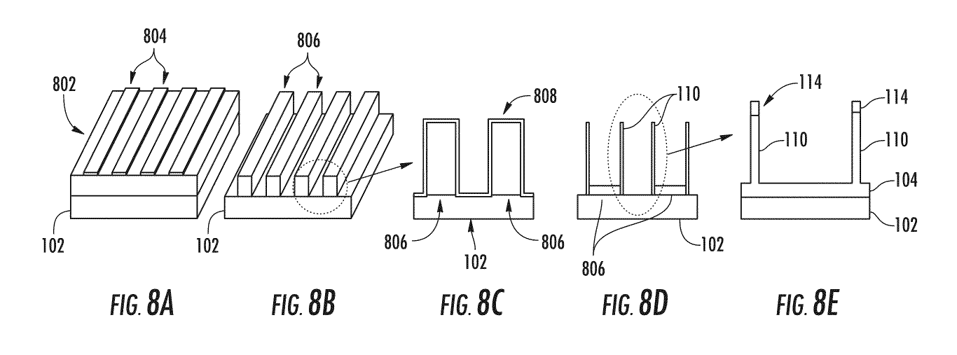

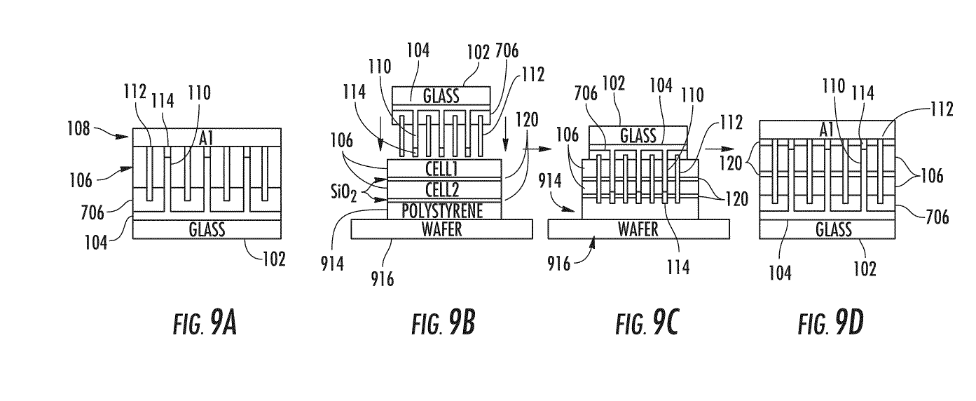

Although an exemplary process for achieving the structure in FIG. 7B has been described; the various embodiments of the invention are not limited in this regard. An alternative process is illustrated in FIGS. 8A-8E. FIGS. 8A-8E show various views during an alternative process for obtaining the structure in FIG. 7B. IN particular, a template process is illustrated. Such a process provides greater control over electrode spacing and can be used to form any of the structures in FIG. 6A, 6B, or 6C.

The process begins at FIG. 8A with the formation of a sacrificial layer 802 on the substrate 102. A photoresist pattern 804 can then be formed on the sacrificial layer. Thereafter, as shown in FIG. 8B, the photoresist pattern 804 can be transferred into the sacrificial layer 802 to form a template 806 for subsequent formation of electrodes 110. Once the template 806 is formed a layer of electrically conductive material 808 can be deposited. For example, a conformal layer of an electrically conductive material can be deposited using ALD or other processes, as described above.

Following this deposition, a planarization and selective etching step can be performed to remove the portions of layer 808 on top of template 806 and template 806. The planarization process can be performed in a variety of ways. In some embodiments a mechanical or chemical mechanical polishing process can be performed to remove the above-mentioned portions of layer 808 and form electrodes 110. Such a process can be timed or configured to stop on the template 806. After the planarization, a selective etch process can then be used to remove the portions of template 806 remaining between electrodes 110. Depending on the etch process used, a portion of layer 808 may or may not remain after removal of template 806. Accordingly, an additional deposition of electrically conductive material can be performed prior to formation of isolation regions 114 to form bottom electrode 104 on substrate 102. Such a process can also be a conformal deposition process, as described above. Thereafter, the isolation regions can be formed on electrodes 110, as described above with respect to FIG. 7B.

Once the structure in FIG. 7B is achieved, a conformal, an electrically insulating sacrificial layer 706 can be formed, followed by deposition of a layer 708 of material for forming cathodes 112, to form the structure shown in FIG. 7C. For example, an atomic layer deposition (ALD) process can be performed to form a conformal layer of Al₂O₃, on the structure of FIG. 7B but that does not fill the gap between anodes 112. Thereafter, a layer of an electrically conducting metal oxide can be formed to fill these gaps and form the cathodes 112. For example, a gap fill layer of TiO₂, ZnO, or MgₓZn₁₋ₓO can be used, to name a few. However, the various embodiments of the invention are not limited to the materials listed above and any other suitable materials can be used in the various embodiments of the invention.

The structure in FIG. 7C can then be planarized to form the structure in FIG. 7D. That is, a planarization process is used to remove at least the portions of layer 708 on the top of the structure in FIG. 7C. The planarization process can also remove an underlying portion of layer 706, also as shown in FIG. 7D. The planarization process can be performed in a variety of ways. In some embodiments a mechanical or chemical mechanical polishing process can be performed to remove the above-mentioned portions of layers 706 and 708. Such a process can be configured to stop on the insulating portions 114 formed on the ends of anodes 110. In other configurations, a non-selective etch (such as reactive ion etching (RIE)) can be used to remove the top portions of layers 706 and 708.

After the planarization, a selective etch can be applied to the structure in FIG. 7D to remove additional portions of layer 706 to expose anodes 110 and cathodes 112, as shown in FIG. 7E. As further shown in FIG. 7E, a portion of layer 706 is left in the structure to physically support cathodes 112 during subsequent processing and to electrically isolated cathodes 112 form bottom electrode 104.

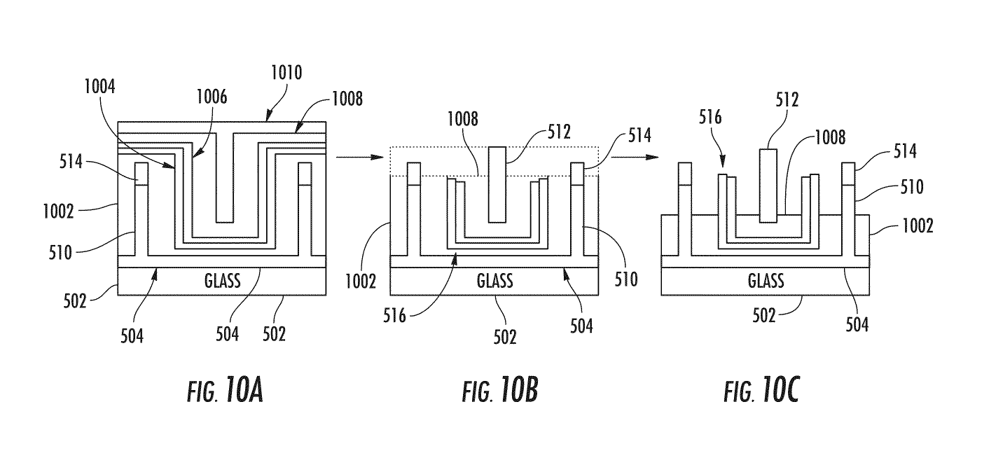

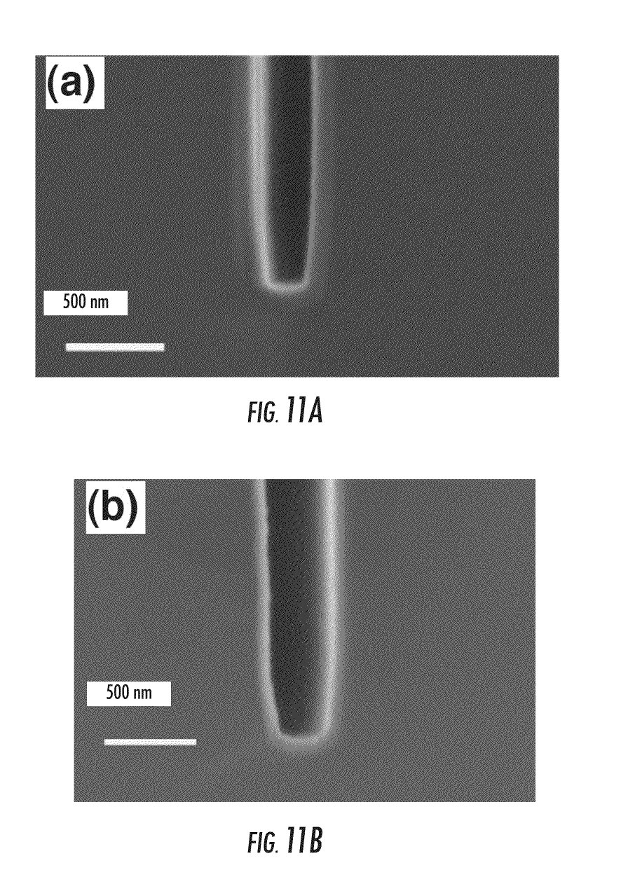

Once the structure in FIG. 7E is formed, the photovoltaic cells can be formed in various ways. In a first method for forming single cells, as shown in FIG. 9A, once the structure in FIG. 7E is formed, the photoactive layer 106 can be formed between the anodes 110 and cathodes 112. In the various embodiments, the photoactive layer 106 can be formed from a variety of materials, including, but not limited to MDMO-PPV:PCBM, MEH-PPV:PCBM, P3HT:PCBM, PBDTTT-E/PCBM, PBDTTT-C/PCBM, PBDTTT-CF/PCBM, and PCPDTBT:PCBM, to name a few. Additionally, the absorption energy bands can be tailored and can include, for example, visible or near-infrared.

The formation of photoactive layer (i.e., the infiltration of the polymer into the spaces between anodes 110 and cathodes 112) can be performed in various ways. For example, various infiltration methods including spin-casting, melt infiltration, dip-coating, and polymerization. Among these, the spin-casting and melt infiltration are generally the most efficient methods for inter-electrode spacing larger than 50 nm. To assure the complete removal of organic blend residue remaining on the top of the device after spin-casting and melt-infiltration, a subsequent short-period exposure to a solvent can be applied to remove such residue.

After the photoactive layer 106 is deposited, the top electrode layer 108 can then be deposited. Layer 108 can be deposited in a variety of ways. For example, the metal can be deposited using a chemical vapor deposition (CVD) process, a ALD process, or a physical deposition process such as evaporation or sputtering. Further, layer 108 can be formed from a variety of materials, including, but not limited to, Al, W, Au, Pt, or any other electrically conducting materials.

As noted above with respect to FIG. 1, a dielectric layer 120 may be interposed within the photoactive layer 106 to provide tandem cells. For the tandem structures, an imprinting method can be used, as shown in FIGS. 9B-9D to provide infiltration of multiple photoactive layers. In the exemplary imprint process shown in FIGS. 9B-9D, polystyrene can first be dissolved in toluene and spin-cast to produce very thick, planar (not nanosphere) polystyrene layers 914 on a flat wafer or substrate 916.

After the polystyrene layer 914 is formed, the active organic layers 106 can be deposited on the on polystyrene layer 814, interspaced with optically transparent, insulating SiO₂ layers 120. The layers 120 can be deposited by electron beam evaporation, for example, and serve as protecting layers for underlying organic films during subsequent spin-casting of active layers 106. It should be noted that SiO₂ will protect photoactive layers from being dissolved in toluene during the removal of polystyrene. In cases where a thicker insulating optical spacer are required in addition to SiO₂, a layer of poly trifluoroethylene (PTrFE), a fully solution processable material, can be used between cells to ensure adequate separation.

In such embodiments, the imprinting temperature will be higher than the glass transition temperature (˜130° C.) of all the organic materials being used, including polystyrene. The layers 106 and 120 are then slowly and carefully infiltrated using low mechanical pressures to provide the structure in FIG. 9C. The temperature and pressure can be selected based on the type of active layer materials and other factors. After imprinting, the polystyrene layer 914 can be removed, for example, using a toluene, to free the electrodes 110, 112 from the wafer 916. After a subsequent drying/curing process, the metal contacts can be made and provide the structure in FIG. 9D. This process is similar to that described for FIG. 9A.

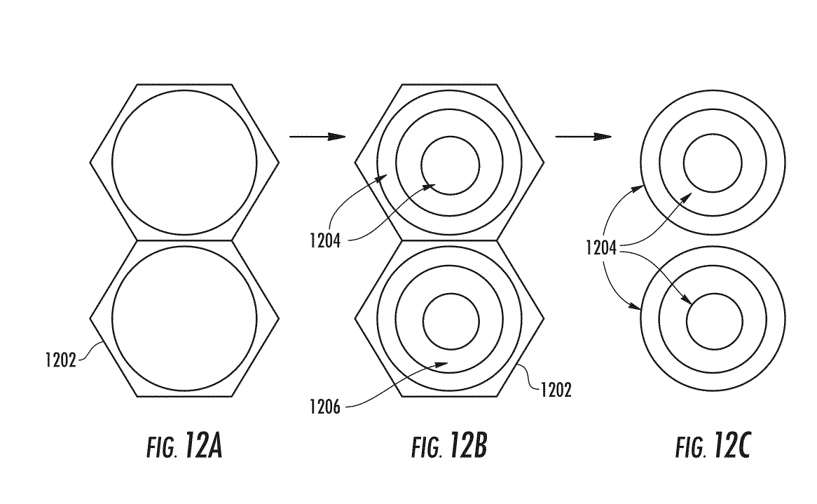

As described above, in some embodiments of the invention, a recombination layer can be formed, as described above with respect to architecture 500 in FIG. 5. However, the process described with respect to FIGS. 7A-7E can still be used with some modifications. These modifications are shown in FIGS. 10A-10C. FIGS. 10A-10C show various views during an exemplary process for fabricating an interdigitated array of photovoltaic cells in accordance with an embodiment of the invention and corresponding to architecture 500.

To provide the recombination layer, after the anodes 510 are formed to provide a structure substantially similar to that shown in FIG. 7B, deposition of various layers can be performed, as shown in FIG. 10A. First, an electrically insulating sacrificial layer 1002 can be formed in a process similar to that described above with respect to FIG. 7A. However, instead of following formation of layer 1002 with deposition of a layer for forming cathodes, conformal recombination layers 1004 and 1006 are deposited. As described above, layers 1004 and 1006 can provide layers of cathode and anode material, respectively, arranged with respect to anode 510 and cathode 512 to form a series tandem cell. Such layers can also be deposited using ALD or other conformal processes. Further, such layers can comprise the same materials as used for forming anodes 510 and 512. Following deposition of the recombination layers 1004 and 1006, an additional conformal layer of electrically insulating material 1008 can be formed on recombination layer, similar to that of layer 1002. It should be noted that the formation of layers 1002-1008 is configured to prevent the gap between anodes 510 from being completed filled. Finally, a layer of electrically conductive material 1010 can be deposited over layer 1008 and configured to fill the gaps between anodes 510 and define cathodes 512, similar to layer 708 in FIG. 7C.

Once the structure in FIG. 10A is achieved, the planarization of the structure in FIG. 10A can be performed, followed by a selective etch of layers 1002-1008, to provide the structure in FIG. 10B, including defining cathodes 512. As described above, various type of mechanical, chemical-mechanical, and other dry or wet etching processes can be used to selectively remove the portions of the 1002-1010 and define cathodes 512 and recombination center 516. Thereafter, a selective etch of layers 1002 and 1008 can be performed to expose portions anode 510, cathode 512, and the recombination center 516 to provide the structure in FIG. 10C. A photoactive layer(s) and a top electrode layer can then be formed according to any of the processes described above with respect to FIGS. 9A-9D.

The processes described above utilize processes for forming conformal electrically insulating and electrically conducting layers. As described above, such conformal growth techniques can include atomic layer deposition (ALD). However, the various embodiments of the invention, other methods can be used, such as pulsed-plasma enhanced chemical vapor deposition (pulsed-PECVD).

Both deposition systems can be used to deposit metal oxides and metals of Al₂O₃, TiO₂, ZnO, NiO, MoO₃, WO3, Pt, and other materials suitable for photovoltaic cells. Further, both ALD and pulsed-PECVD techniques offer unique characteristics like excellent large-area uniformity, atomic level control of film thickness, and superior conformal step coverage on complex, non-planar surface topographies with extremely high aspect ratio. In particular, pulsed-PECVD generally offers similar versatility at lower temperatures that ALD provides, but higher growth deposition is possible. For example, in the case of Al₂O₃ deposition, Al(CH₃)₃ (TMA) and water vapor are used for ALD while PECVD uses TMA and O₂ as oxygen plasma to accelerate the deposition reaction at the lower growth temperature. ALD Al₂O₃ has a deposition rate of around 1 Å/cycle while pulsed-PECVD growth rate of Al₂O₃ can be increased up to 10 Å/cycle by adjusting the TMA vapor pressure and pulsed plasma power at the growth temperature of less than 200° C. However, even with such a higher growth rate, almost the same conformal deposition in non-planar surface can be achieved, as shown in FIGS. 11A and 11B. FIGS. 11A and 11B show cross-sectional SEM images of Al₂O₃ at the bottom of 5 μm deep trench for an ALD process and pulsed PECVD process, respectively. As shown in FIGS. 9A and 9B, the two deposition processes result in substantially the same conformality.

Tube-in-Tube Photovoltaic Cells Fabrication

As described above, the various embodiments are not limited to arrays of cathode and electrode portions. Rather, in some embodiments of the invention, photovoltaic devices based on tube-in-tube (or rod-in-tube) cells are provided, such as that schematically shown in FIG. 6C. In such embodiments of the invention, these cells can be fabricated using a template method. This is schematically illustrated in FIGS. 12A-12C.

FIGS. 12A-12C schematically illustrate a method of fabricating photovoltaic cells using a tube-in-tube method based on a template. For example, the template can be formed as described above with respect to FIGS. 8A-8E. First, as shown in FIG. 12A, a template 1202 of pores or openings is provided. Several methods for generating such a template will be described below in greater detail. Afterwards, alternating layers of metals or conducting metals oxides 1204 and sacrificial spacers 1206 (i.e., insulating layers) can be conformally deposited, similar to the processes described above, to provide the structures in FIG. 12B. Finally, selective chemical etching of the spacers 1206 and the template 1202 can be used to remove expose the metal or metal oxide tubes (or rods), i.e., the carrier collection structures, prior to deposition of the photoactive layer, as shown in FIG. 12C. The templates required for such structures can be generated in several ways in the various embodiments of the invention.

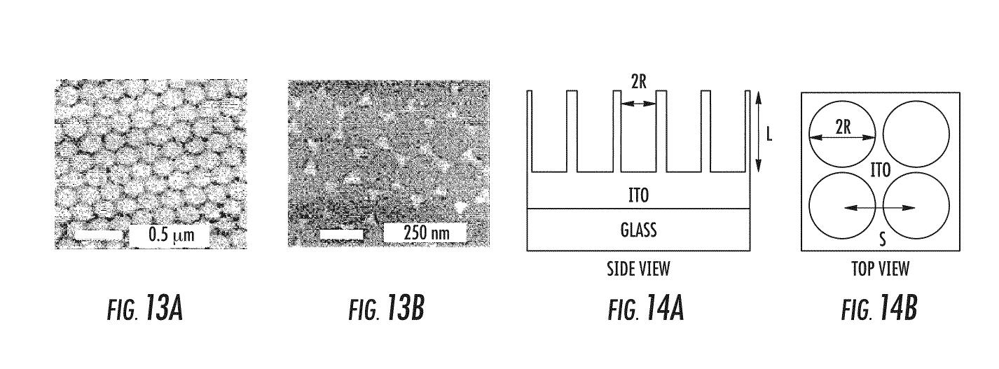

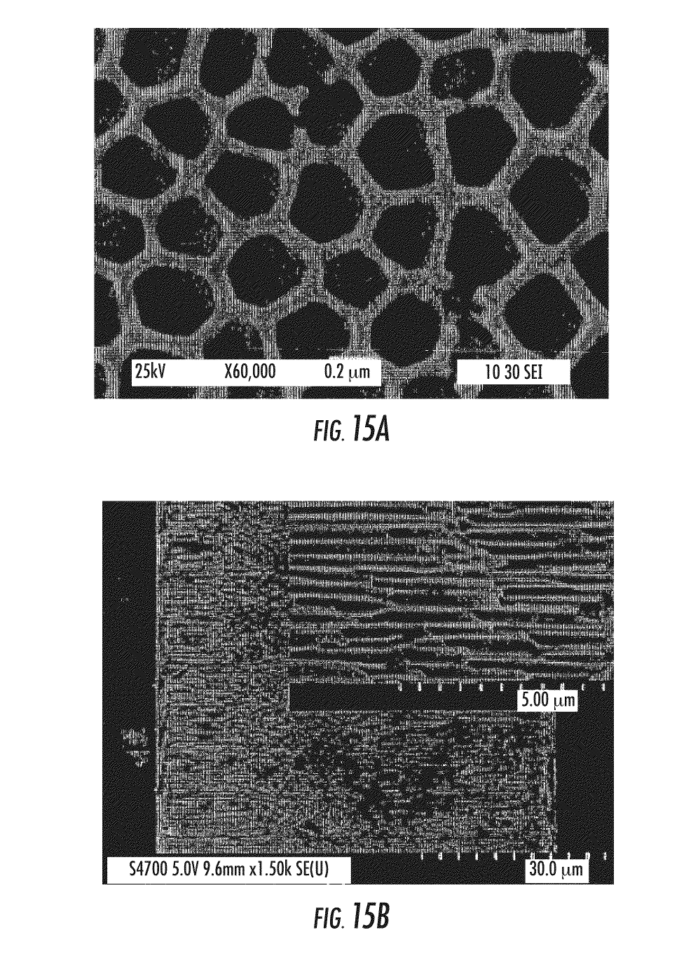

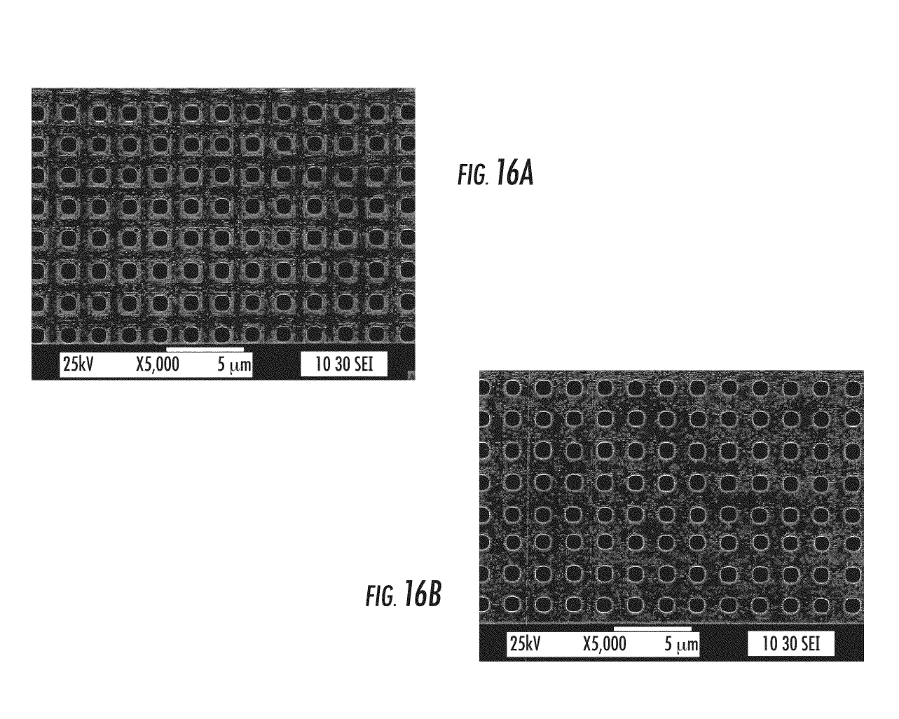

For example, in one embodiment of the invention, polystyrene (PS) nanosphere lithography can be used to directly produce nanopore templates on thick ITO deposited on glass. In such processes, a self-organized, monodispersed PS layer is first formed on a substrate of ITO/glass. Second, an inverse pattern is provided via formation of a ITO etch mask defined by the interstitial voids between the nanospheres. This is shown in FIGS. 13A and 1313. FIG. 13A is a top-down SEM image of mono dispersed polystyrene nanosphere on an ITO/glass surface. FIG. 13B is a top-down SEM image of the ITO/glass surface showing the nanoscale metal mask patterns obtained after nanosphere removal. In such embodiments, the nanohole size in the masks can be controlled by the choice of PS bead size ranging from tens of nanometers to micrometers and by increasing the interstitial voids between nanospheres with oxygen plasma etching. After forming metal masks, dry etching can be performed to create the nanoholes in the ITO layer. The result of this process is shown in FIGS. 14A and 14B. FIG. 14A is a schematic diagram of a side view of an ITO/glass substrate after PS nanosphere lithography. FIG. 14B is a top-down view of the ITO/glass substrate of FIG. 14A.

In the general, the PS nanosphere monolayer can contain many structural defects such as dislocations, vacancies, and randomly occurring disorder. Accordingly, in some embodiments, additional processing to release the PS spheres from the ITO/glass can be performed to allow them to undergo a self-assembly process on the wafer surface. In such a process, two-dimensional PS monolayers generally maintain their shape on the wafer surface but an additional self-assembly process will cure any structural defects and form a defect-free, self-assembled PS layer. The self-assembled, close-packed PS layer can them be transferred onto an ITO surface.

In other embodiments of the invention, the templates can be provided using porous films. For example, in some embodiments, the templates can be formed using a nanoporous anodized aluminum oxide (AAO) film. A nanoporous AAO substrate can be prepared by a two-step anodization procedure. First, high purity aluminum sheets (˜0.5 mm thick) can be degreased using, for example, acetone or any other suitable solvent. These sheets can then be electropolished in a solution of HClO₄ and ethanol. For example, a exemplary process can be performed using a 1:4, v/v solution at 20 V for 5-10 min or until a mirror-like surface is achieved.

Thereafter, a first anodization step can carried out to form a porous alumina layer on the surface of the sheet. For example, an exemplary process can include anodization in a 0.3 M oxalic acid solution electrolyte under a constant direct current (DC) voltage of 80 V at 17° C. for 24 h. After the first anodization step, the porous alumina layer can be stripped away from the Al substrate. For example, the stripping can be performed by treating the anodized sheet using a solution containing 6 wt % phosphoric acid and 1.8 wt % chromic acid at 60° C. for 12 h. A second anodization step can then be carried out. For example, the Al sheet can be treated using a 0.3 M oxalic acid solution under a constant direct current (DC) voltage of 80 V at 17° C. for 24 h. Finally, AAO substrates with highly ordered arrays of pores can be obtained by selectively etching away the unreacted Al and, if necessary performing planarization of the AAO substrate. For example, the unreacted Al can be etched away using a saturated HgCl₂ solution. The planarization can then be performed using ion milling.

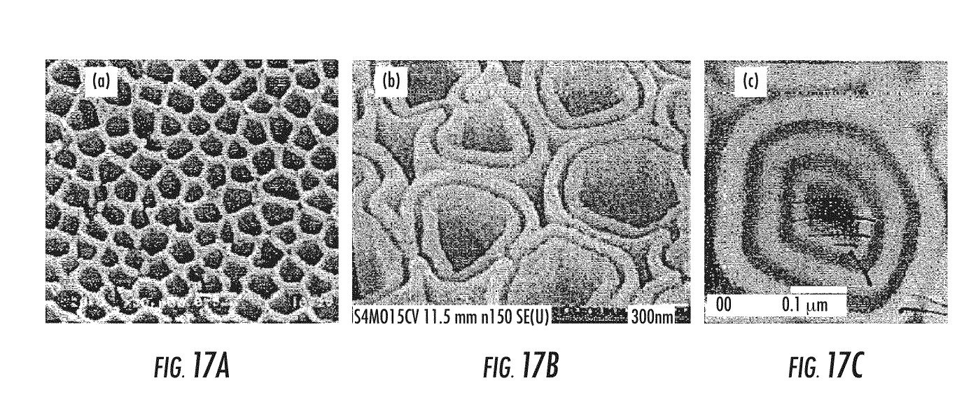

An exemplary result of the above-mentioned processes is illustrated in FIGS. 15A and 15B. FIG. 15A show a top-down and cleaved scanning electron microscope (SEM) images, respectively, of the pore structure of a 140 μm thick, planarized AAO substrate. As shown in FIG. 15A, the resulting pore size is in the range of 200-300 nm and the wall width between pores is approximately 130 nm. As can be observed in FIG. 15A, some of the pores were connected via thinning of the wall. As shown in FIG. 15B, the pores are substantially parallel to each other. The inset in FIG. 15B shows the formation of branches in some of the pores. Such branches can be eliminated by using shorter anodization times, although this results in a shorter pore length.

High magnification FE-SEM of such samples also shows a smooth morphology of the inside walls of the AAO pores can be achieved. Such smooth wall formation is generally desirable, as the process using for forming subsequent layers in the pores replicate the surface of the pores in the membrane on an Angstrom scale.

However, the various embodiments of the invention are not limited solely to AAO-based porous membranes. In other embodiments the porous membranes can be formed using silicon or other types of semiconductor substrates. In such a process flow, openings can formed in the semiconductor substrate via photolithography processes followed by substrate etching processes. Accordingly, this process flow can include deposition and removal of photoresist, deposition and etching of masking layers, and cleaning or degreasing steps. The advantage of such a photolithography-based process is that the size and spacing of the pores can be directly controlled. Accordingly, the ordered porous membranes can be more reliably and reproducibly manufactured. For example, the result of such a process is shown in FIGS. 16A and 16B.

FIGS. 16A and 16A are SEM images of the front side and back side, respectively, of a silicon substrate-based porous membrane. As shown in FIGS. 16A and 16B, the pores are substantially identical and arranged in a regular array. Further, since more control over size and spacing of the pores is provided, issues regarding branching or connected pores are eliminated. Additional, the etch process or post-etch processes can be configured to provided relatively smooth surface in the pores.

In still other embodiments, a template can be formed as described above with respect to FIGS. 8A-8E. In such configurations, the sacrificial layer, such as an oxide layer, can be formed on the substrate onto which the electrodes are to be disposed on. Thereafter pores can be formed using etch processes. Thus, similar to the silicon substrates described above, an array of openings can be provided.

Although various exemplary processes have been described above, the various embodiments of the invention are not limited in this regard. Rather, one of ordinary skill in the art will readily recognize that other process can be used to form porous membranes and layers in accordance with the various embodiments of the invention.

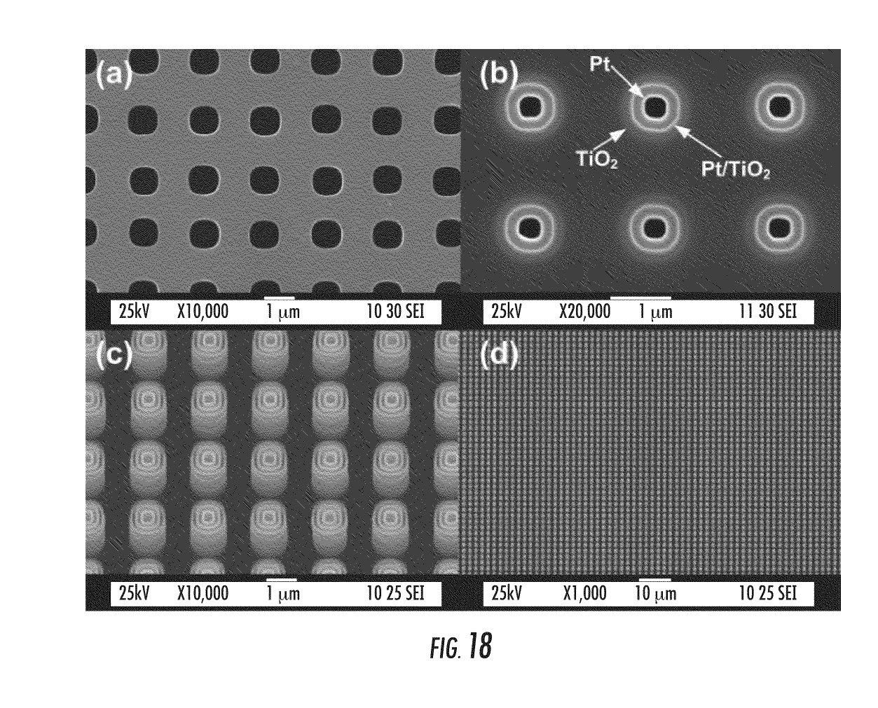

Referring back to FIGS. 12A-12C, Regardless of how the templates are formed, the template is used to guide the deposition of conformal metal oxide layers (to form anodes and cathodes) and sacrificial spacer portions. Thereafter, a selective etch process can be used to create the well-ordered, multilayered tube-in tube (or rod-in-tube) structures. This is illustrated in FIGS. 17A-15C for AAO templates. FIGS. 17A-15C show various SEM images of the results of tube formation processes based on an AAO template. FIG. 17A is an SEM image of single ZnO tubes after AAO removal. FIG. 17B is an SEM image of double HfO₂ tubes after AAO removal. FIG. 17C is an SEM image of triple ZrO₂ tubes after AAO removal. FIG. 18 shows a similar result for a template form from lithography of a silicon substrate, as described above. FIG. 18 shows various SEM images of the tube-in-tube formation process using a template formed from a silicon substrate. As shown in portion (a), the template can be defined, as described above. Thereafter, conformal deposition processes can be used to deposit the various layers in the openings, as shown in portion (b). The template can then be removed to provide an array of cells over a large area, as shown in portions (c) and (d).

Since the spacing between metal oxides can be controlled by manipulating spacer wall thickness, the template-guided technique allows for control of electrode spacing within an atomic resolution by simply adjusting the thickness of concentric sacrificial spacers.

Selective Etch Processes

Regardless of how the anodes and cathodes are arranged, the various embodiments of the invention utilize selective chemical etching methods for removing the various spacer materials and (if necessary) for removing template materials without the removal of the various metal oxides needed for the anodes and cathodes. FIGS. 19A and 19B present the thermodynamic modeling diagrams for Al₂O₃ and ZnO and show the distributions of the fraction of all species at different pH values calculated at 298 K for a 0.001 mM solution. In the case of crystalline Al₂O₃, the fraction of Al(OH)₃ in solution presents as solid Al₂O₃ (after water removal). The formation of solid alumina is in the pH range from 4.2 to 9.8 while solid ZnO lies in a range from 9.2 to 11.5. Therefore, thermodynamic modeling indicates that effective dissolving conditions for Al₂O₃ spacers should be at large pH values in order to simultaneously avoid attacking ZnO surfaces. For example, the dissolving conditions that result in minimum preferential etch attacks to ZnO surfaces can be obtained by selection of a buffered solution with a pH of 9.2-11.5.

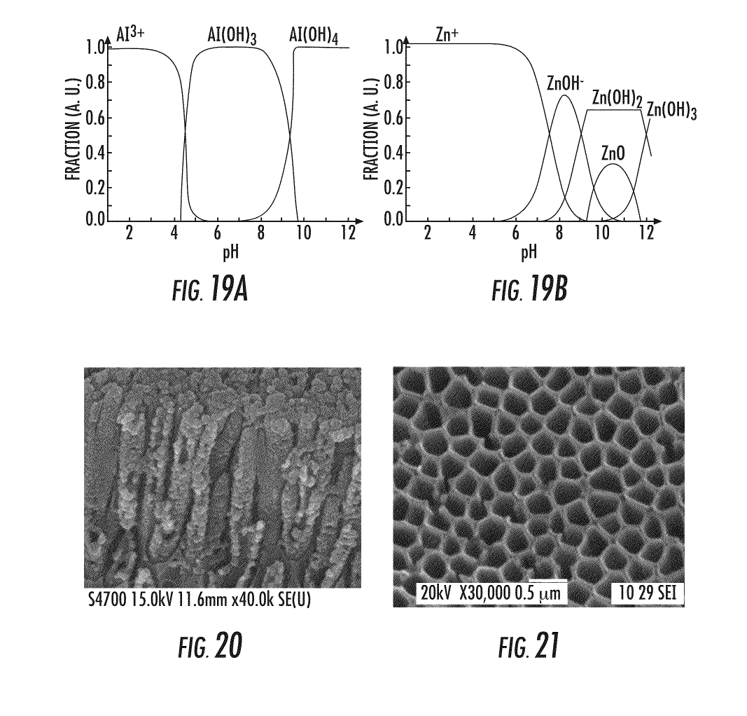

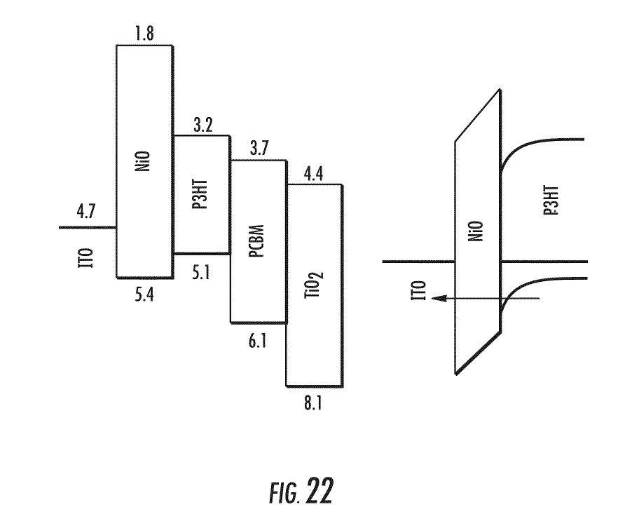

However, the crystallinity of oxides, in addition to selecting the proper pH values, can also impact preferential etching along grain boundaries at the surface. This is illustrated in FIG. 20. FIG. 20 is a SEM image of cleaved ZnO nanotubes released from an AAO template. FIG. 20 shows ZnO nanotubes that were preferentially etched along the grain boundaries even though the proper pH value for selectively etching Al₂O₃ was used. In contrast, well-defined ZnO nanotubes are released from Al₂O₃ nanopore templates after thermal treatment using the same pH value. For example, FIG. 21 is a SEM image of cleaved ZnO nanotubes released from an AAO template after an anneal process. Accordingly, in some embodiments of the invention, an anneal process, prior to selective etching, can be provided to improve selectively of the subsequent etch.

Modification of Interfacial Layer Between Organic and Inorganic Materials

In some embodiments, the interfacial charge dynamics can be adjusted to charge extraction from organic interfaces to electrodes while recombination processes at the interfaces should be suppressed. Thus, an ITO and anodic metal require chemical modification to prevent reactive degradation of its surfaces and to tune its work function so that a balanced charge extraction process can be established. For example, surface modification of anodic metal of Pt can be carried out with transition metal oxides, as described below.

NiO oxide forms metal (M)-insulating (i)-organic (S) semiconductor interfaces so that the interfacial contact behaves like an MIS structure, as shown in FIG. 22. FIG. 22 is a schematic of the energy level of polymer-fullerene/electrode (left) and band alignment at the anode interface after contact (right). In such a configuration, charge carriers cross the NiO layer by tunneling. When the thickness of the NiO increases, the probability of tunneling decreases. (It is worth noting that a Ni₂+ vacancy-based impurity energy band located above the valance bandgap may be available for holes to transfer through to the Pt, giving rise to an effective tunneling current even with thicker NiO films.) Therefore, the thickness of NiO can be adjusted to balance tunneling effects.

NiO has additional advantages for controlling recombination at the interface. Energy band alignments indicate that NiO acts as the electron-blocking interfacial layer between the ITO anode and organic blends. This interfacial configuration can significantly reduce the dark current and thereby increase VOC since these parameters have an inverse relationship. In addition, the increased built-in potential that results from introducing NiO interfacial layers can also increase VOC since VOC corresponds to the voltage where the applied bias equals the built-in potential in an ideal diode.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

What is claimed is:

1. A device comprising:
at least one photovoltaic cell comprising at least one first electrode layer, at least one photoactive layer disposed on first electrode layer, at least one second electrode layer disposed on the photoactive layer, at least one first carrier collector structure with a first work function electrically coupled to the first electrode layer and extending partially in to the photoactive layer, and at least one second carrier collector structure with a second work function different from the first work function electrically coupled to the second electrode layer and extending partially into the photoactive layer,
wherein the first carrier collector structure extends towards the second electrode layer without physically contacting the second carrier collector structure, wherein the second carrier collector structure extends towards the first electrode layer without physically contacting the first carrier collector structure, wherein at least one of the first and second electrode layers is optically transparent.

2. The device of claim 1, wherein the at least one photoactive layer comprises:
at least a first photoactive layer;
at least one transparent electrically insulating layer disposed on the first photoactive layer, and
at least a second photoactive layer disposed on the insulating layer.

3. The device of claim 1, wherein the first and second carrier collector structures are substantially parallel to each other.

4. The device of claim 1, wherein the photovoltaic cell further comprises:
at least one recombination center disposed in the photoactive layer between the first and second carrier collector structures and which does not contact the first and second carrier collector structures.

5. The device of claim 1, wherein the first carrier collector structure comprises a tube structure, and wherein the second carrier collector structure comprises one of a tube structure or a rod structure in a coaxial arrangement with the first earner collector structure.

6. The device of claim 1, wherein the photoactive layer comprises at least one organic polymer.

7. The device of claim 1, wherein a spacing between the first and second carrier collector structures is about 1 nm to about 500 nm.

8. The device of claim 1, wherein at least one of the first and the second carrier collector structures comprises a metal oxide.

10. The device of claim 15, wherein the metal oxide comprises at least one of TiO₂ and ZnO.

11. The device of claim 1, wherein the metal oxide comprises at least one of ITO, MoO₃, V₂O₅, WO₃, NiO, Pt, and Au.

12. The device of claim 1, wherein the metal oxide comprises a nanostructured metal oxide, the nanostructured metal oxide comprising at least one of TiO₂, ZnO, ITO, MoO₃, V₂O₅, WO₃, NiO.

13. The device of claim 1, wherein the device further comprises at least one hole transport layer.

14. The device of claim 1, wherein the device further comprises at least one conformally deposited hole transport layer.

15. The device of claim 1, wherein the cell comprises sub-cells of different energy bandgaps for expansion of spectral absorption range.

16. The device of claim 1, wherein the first and second carrier collector structures comprise nanostructures having an aspect ratio of at least about 300.

17. The device of claim 1, wherein the first carrier collector structure and the first electrode layer are integrally formed.

18. A method of fabricating a photovoltaic device, comprising:
forming a first electrode layer that is optically transparent and electrically conductive, the first electrode layer comprising a plurality of first carrier collector structures;
forming one or more conformal layers over the upper surface of the first electrode layer defining one or more gap regions between adjacent ones of the plurality of first carrier collection structures, the conformal layers comprising at least a first electrically insulating layer;
depositing at least one electrically conductive layer over the conformal layers, the electrically conductive layer configured to substantially fill the gap regions;
removing at least a portion of the electrically conductive layer to define a plurality of isolated second carrier collection structures between the plurality of first carrier collection structures; and
removing a portion of the conformal layers to expose sidewall portions of the plurality of first carrier collection structures and sidewall portions of the plurality of second carrier collection structures.

19. The method of claim 18, wherein the conformal layers are formed using atomic layer deposition or pulsed plasma-enhanced chemical vapor deposition.

20. The method of claim 18, further comprising:
forming at least one photoactive layer between the exposed portions of the plurality of first carrier collection structures and the exposed portions of the plurality of second carrier collection structures; and
forming a second electrode layer over the photoactive layer and in electrical contact with the plurality of second carrier collection structures without contacting the plurality of first carrier collection structures.

21. The method of claim 1, wherein the photoactive layer comprises at least one organic polymer.

22. The method of claim 20, wherein the at least one photoactive layer comprises:
at least a first photoactive layer;
at least one transparent electrically insulating layer disposed on the first photoactive layer, and
at least a second photoactive layer disposed on the insulating layer.

23. The method of claim 18, wherein the step of forming the first electrode layer comprises selecting each of the plurality of first carrier collection structures to comprise one of a tube, a rod, or a wire.

24. The method of claim 18, wherein the step of depositing further comprises depositing recombination center layers on the first electrically insulating layer, and depositing at least a second electrically insulating layer on the recombination center layers.

25. The method of claim 18, wherein the step of forming the first electrode layer comprises further comprises selecting the plurality of first carrier collection structure to extend in a direction substantially perpendicular to the upper surface of the bottom electrode layer.

26. The method of claim 18, wherein the step of forming the first electrode layer comprises
forming a template on a substrate, the template having one or more openings;
defining the plurality of first carrier collection structures on the sidewalls of the openings; and
removing the template.
